(19) United States
(12) Patent Application Publication
(10) Pub. No.: US 2009/0115465 A1
(43) Pub. Date: May 7, 2009

(54) LOW POWER, HIGH SLEW RATE CCD DRIVER

(75) Inventors: Richard Hernandez GARCIA, Singapore (SG); Shao Hai WU, Singapore (SG)

Correspondence Address: GREENBLUM & BERNSTEIN, P.L.C., 1950 ROLAND CLARKE PLACE, RESTON, VA, 20191, US

(73) Assignees: MATSUSHITA ELECTRIC INDUSTRIAL CO., LTD., Osaka (JP); PANASONIC SEMICONDUCTOR ASIA PTE., LTD., Singapore (SG)

(21) Appl. No.: 11/934,898

(22) Filed: Nov. 5, 2007

(51) Int. Cl. H03K 19/003

(52) U.S. Cl. 327/111; 327/170

(57) ABSTRACT

A low power, high slew rate output driver circuit system is provided. The Circuit system comprises a cascade of two high-speed stages and a variable current biasing block. The combination of these two elements enables the realization of a high slew rate, yet low power output driver system.

### BACKGROUND OF THE INVENTION

The present invention relates to a CCD Buffer/Driver having a quick settling time during a high slew rate, hence overshoot/undershoot. More particularly, to a method to maintain low Quiescent Current (ICQ) while maintaining a high performance.

FIGS. 1A and 1B shows the conventional method of CCD Buffer/Driver using discrete components. In the example shown in FIG. 1A, a discrete NPN transistor Q1, with its emitter connected to a current sink S1 is connected as a Class A Output Buffer. Alternative Connection for a Class A Output Buffer is to connect emitter of transistor Q1 to a large resistor instead of Current Sink S1, as shown in FIG. 1B. PNP Transistors can be used to form the Class A Output Buffer to obtain similar function.

FIG. 2 shows another Prior Art, in schematic level, used commonly for CCD Buffer/Driver application, using integrated circuits. In this example, a Class A Output Buffer Stage A1 is connected as Pre-Amplifier Stage followed by a Class AB Output Buffer Stage AB1.

One main issue faced by both conventional arts relates to the Slew Rate performance versus Current Consumption. Based on both the conventional arts, for a good Slew Rate, e.g. 450 V/us, the Quiescent Current needed by the IC would be very high, and likewise, to maintain a relatively low ICQ, e.g. 1.5 mA, the Slew Rate performance would be much lesser than 450 V/us.

In both conventional arts, Class A Output Buffer Stage is used. Using FIG. 1 as example, the maximum rising and falling Slew Rate will not be well matched unless a large Sinking current is applied, as, in the case of a NPN Class A buffer, the maximum falling speed is limited by the sink current. In actual application of CCD Drivers, it is important to maintain low ICQ while keeping the high slew Rate Performance.

Also, according to actual application of CCD Driver, input signal (similar to Square pulses) at tens of MHz, e.g. 50 MHz, enter the Buffer at a high Slew Rate. To maintain the shape of the output signal to be similar to that of the input signal, both minimum rise and fall Slew Rate is to be same as, if not better than, the input signal.

### SUMMARY OF THE INVENTION

The purpose of this invention is to provide a method to control the ICQ while keeping the Slew Rate Performance to be high. Two high speed stages in the form of Pre-Amplifier and Output Stages are cascaded to achieve the high slew rate. Two Variable Current Biasing Blocks are also utilized to achieve a variable biasing current for the Output Stage, which in turn translates to having an overall lower power consumption compared to conventional drivers that employ fixed biasing currents.

### BRIEF DESCRIPTION OF THE DRAWINGS

FIGS. 1A and 1B are diagrams showing the conventional art of the application using discrete components;

FIG. 2 is a diagram of another Prior Art, in schematic level, used commonly in integrated IC form;

FIG. 3 is a circuit diagram of the first preferred embodiment of the present invention.

FIG. 4 is a circuit diagram of the actual circuit implementation of the Pre-Amplifier Stage of the mentioned invention base on the first embodiment, which is the second preferred embodiment.

FIG. 5 shows the test circuit on application using the second preferred embodiment with load connected.

FIG. 6 shows a circuit diagram on the actual circuit implementing of the variable current biasing block of the mentioned invention in the first and second preferred embodiment.

FIGS. 7A and 7B show the third preferred embodiment which is a further enhancement of the second preferred embodiment to obtain better Slew Rate Performance.

FIG. 8 shows a simulation results comparison using the Prior Art, the second preferred embodiment and the third preferred embodiment.

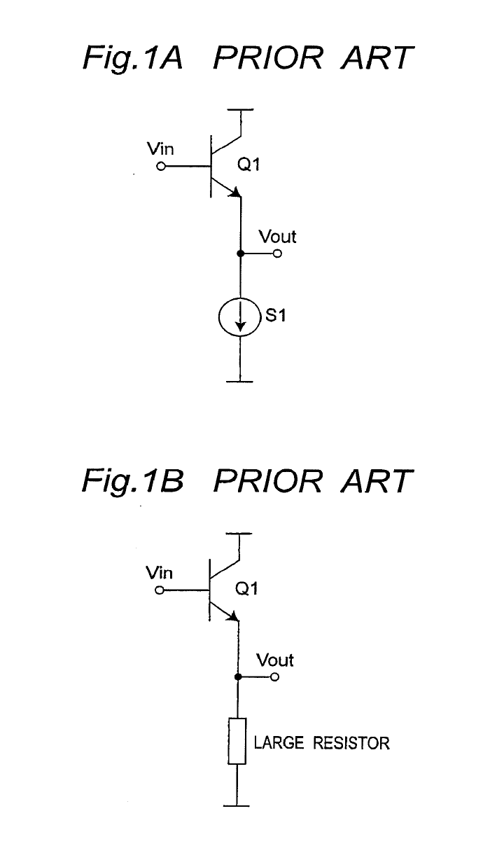

### DETAILED DESCRIPTION OF THE PREFERRED EMBODIMENTS

The following description explains the best mode embodiment of the present invention.

FIG. 3 shows the first preferred embodiment according to the present invention. A high-speed Pre-amplifier stage 102 is cascaded with a High Speed Output Stage 103. Device 104 is an example of such a high speed amplifier with a high slew rate. Variable Current Biasing Blocks 101a and 101b are connected to device 104 so as to sample its output biasing current. The output stage makes use of the same Class AB stage as per conventional art.

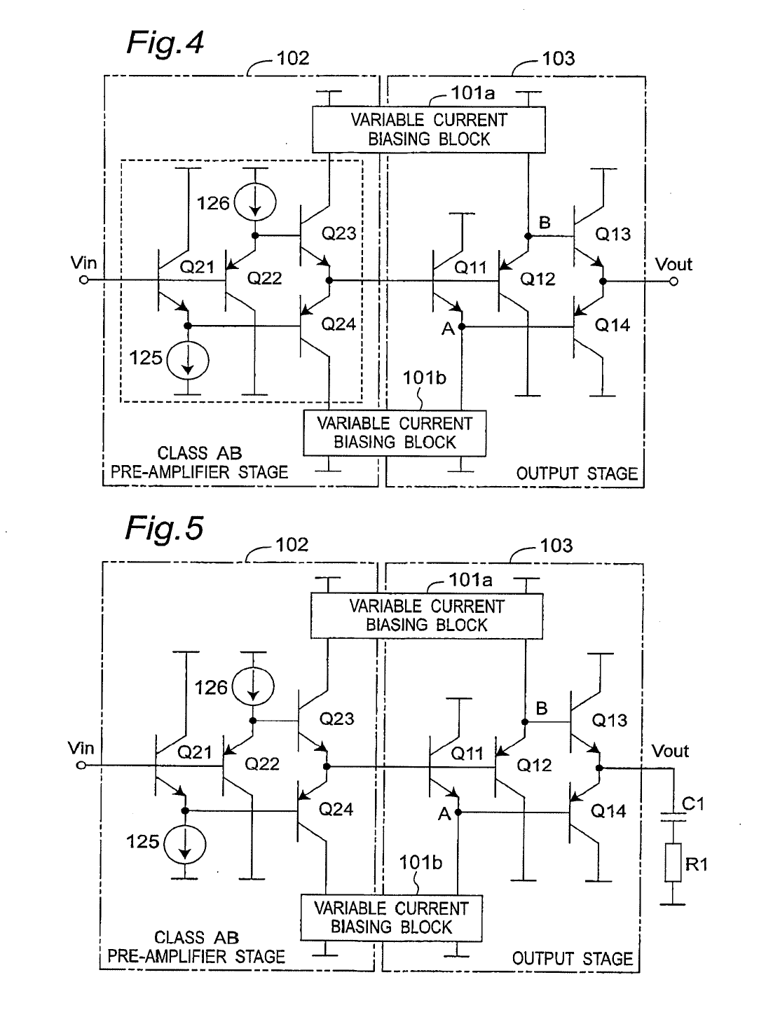

FIG. 4 shows an exemplary embodiment of a second preferred embodiment based on the present invention. Device 104 is exemplarily implemented using a typical Class AB stage. This comprises of Q21 and Q22 being the input stage; Q23 and Q24 being the output stage; Constant Current Sources 125 and 126 providing constant biasing currents for Q21 and Q22. Hence, collectively, the High Speed Pre-Amplifier Stage may also be called as Class AB Pre-Amplifier Stage 102.

Next, the operation of such an arrangement is described below.

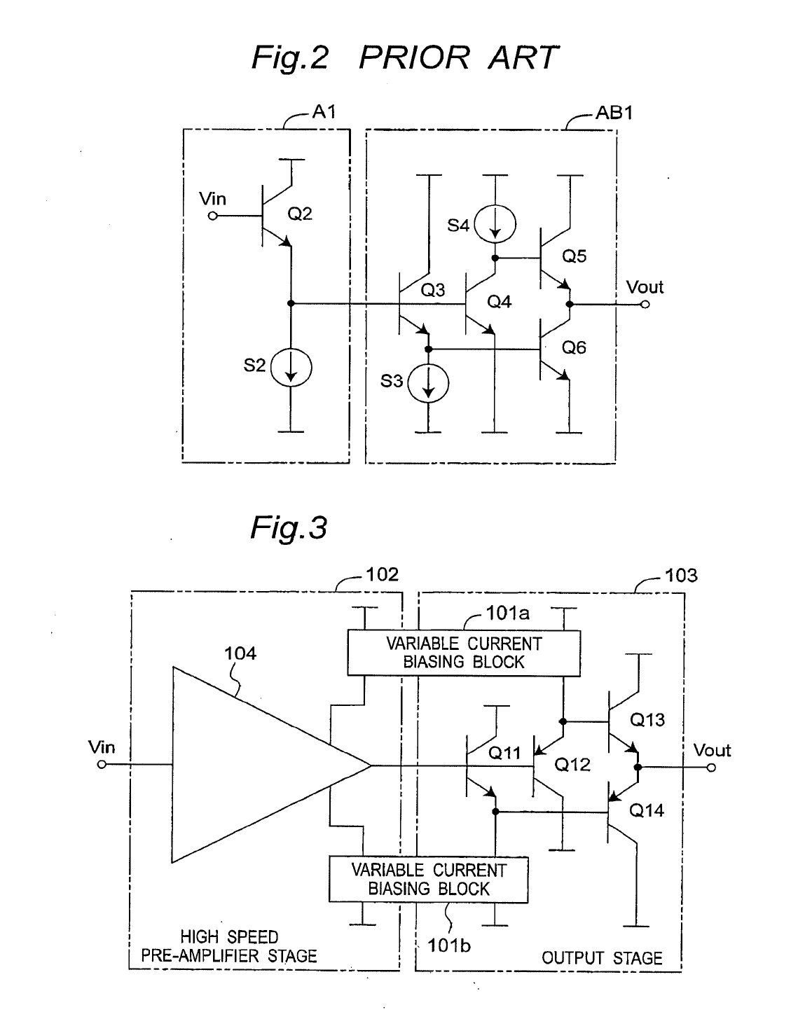

The Class AB Pre-Amplifier Stage is used instead of the conventional Class A Output Buffer Stage for better Slew Rate Performance. During operation, the variable current biasing blocks 101a and 101b will automatically increase its current output according to input transition. The variable current biasing blocks are used to replace the constant current biasing S3 and S4 (See FIG. 2) used in design of a Class AB Output Stage to provide Current Drive Capability to the Output Transistors Q13 and Q14.

FIG. 5 shows the second preferred embodiment driving an AFE, Analog Front End, modeled as a capacitive load C1 in series with a resistive load R1. A Pre-Amplifier Stage 102 is needed to provide current drive to the input of the Output Stage 103. If there is no Pre-Amplifier Stage 102, Input Voltage Signal, Vin, would need to provide the current needed by a single stage buffer, which is very high (even though driving a base) during signal transition. This will cause distortion to Vin. Also, this would mean bigger output transistors needed, and hence more parasitic components causing a further reduction in Slew Rate.

As shown in FIG. 5, analog input voltage, Vin is applied into the base terminals of the npn and pnp input transistors 021 and Q22. Vin is buffered by the Pre-Amplifier Stage 102, which provide the necessary current drive needed by the Output Stage 103, and enters input stage of the Output Stage 103. During operation, the current flowing through the collector terminals of transistors 023 and Q24 will vary due to input signal level transitions.

During operation, when there is no change in input signal level, Vin, little current will flow to the capacitive load C1 and hence, the output stage's 103 current will be kept at quiescent condition, magnitude in the range of several uA. The collector current flowing through Pre-Amplifier Stage's 102 Output Transistors Q23 and Q24 is sensed by the variable current biasing blocks 101a and 101b. The change will be reflected by the variable current biasing block 101a and 101b to the node A connecting the emitter terminal of Q11 and the base terminal of Q14 as well as the node B connecting the emitter terminal of Q12 and the base terminal of Q13 respectively. The current entering the nodes at the Output Stage 103 is therefore reduced and the quiescent current, ICQ, and hence power consumption, will be reduced further as the Output Stage 103 is the major ICQ contributor of the whole system.

When there is a transition in signal level, Vin, current flowing into (or out of, depending on direction of transition) the system will increase abruptly, with change in magnitude from uA to mA. The reason is as follows. This increase in load demand is reflected onto the Pre-Amplifier Stage 102 and the collector current flowing through the Pre-Amplifier Stage's 102 Output Transistors Q23 and Q24 will also increase. This increase in current flow is sensed and reflected to the variable current biasing block 101a and 101b, which will increase the Drive Capability of the Output Stage 103.

Comparing with the Conventional Arts, the Rising Slew Rate and the Falling Slew Rate can be better matched in this invention as both the Pre-Amplifier Stage 102 and the Output Stage 103 are using high speed Class AB configuration. Also, when a push-pull pair is used, here referring to a Class AB configuration, less current is consumed compare to a Class A Buffer Stage.

However, using 2 Class AB in Cascade only cannot contribute to a low ICQ and high Slew Rate Performance on a CCD Driver. Therefore, a variable current biasing block 101a and 101b is required to achieve the required low ICQ.

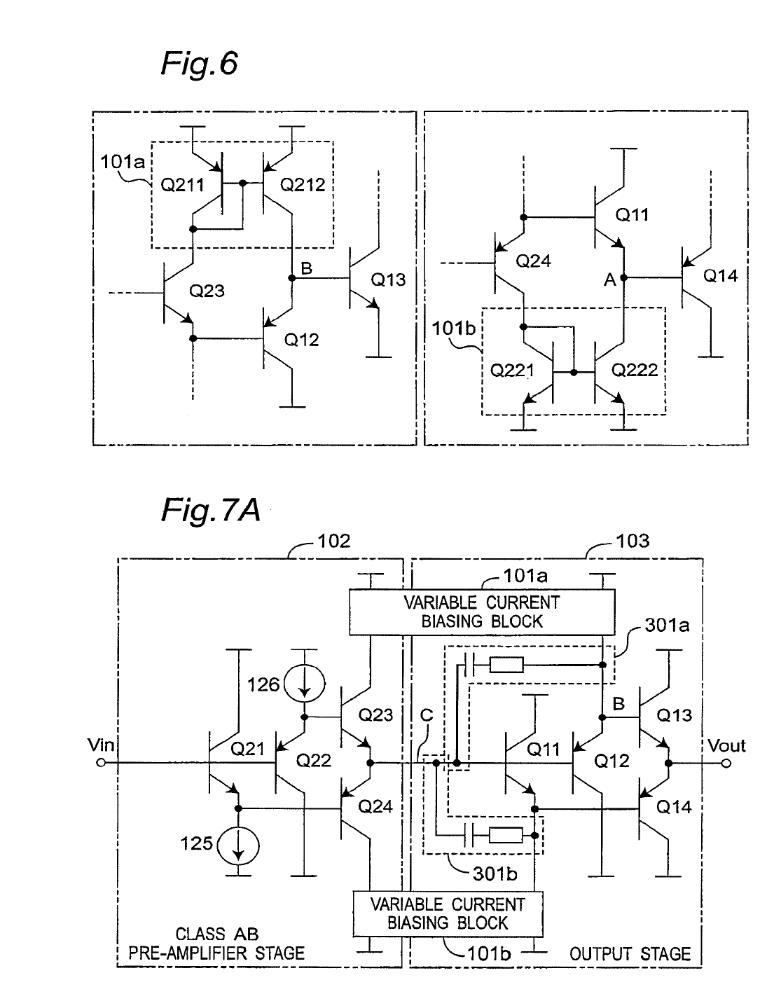

Referring to FIG. 6, an exemplary circuit of an embodiment of the Variable Current Biasing Blocks 101a and 101b as described in first and second preferred embodiment is shown. In the example, current mirror, with the diode connected transistor Q211 and Q221 connected to the collector of the Pre-Amplifier Stage's 102 Output Transistors Q23 and Q24 respectively. The diode connected transistors Q211 and Q221 acts as current sensing devices and transistors Q212 and Q222 mirrors out a ratio/multiple of the sensed current magnitude to nodes A and B. The change in current entering nodes A and B will change the Drive Capability of the Output Transistors Q13 and Q14, and more Drive Capability means better Slew Rate as Slew Rate is directly affected by Drive Capability. Also, more current flowing into the nodes A and B means that the parasitic capacitances are charged up faster, giving faster response.

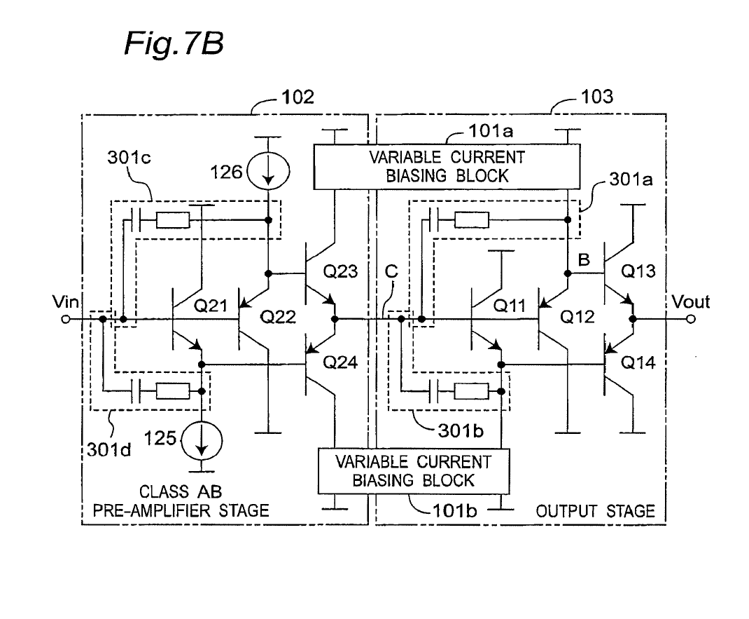

FIG. 7A shows the third preferred embodiment used to further enhance the invention described in the first preferred embodiment and second preferred embodiment. In this example, the configuration of the Pre-Amplifier Stage 102, Output Stage 103 and Variable Current Biasing Blocks 101a and 101b are similar to the second preferred embodiment described above. The enhancement made consists of adding a simple capacitive feed-forward network to the invention, namely adding the network of capacitor and resistor in series 301a and 301b connected from node C to the base terminals of the output transistors Q13 and Q14 of the Output Stage 103. This enhancement added to the invention further improves the Slew Rate of the system. Unlike the usual function of a feed-forward network which is to create a high-frequency bypass around a bandwidth bottle-neck which contributes a substantial amount of phase shift, this feed-forward network 301a and 301b function to pre-excite the output transistors Q13 and Q14 such that Q13 and Q14 will react to the signal change before the collector of Q11 and Q12 starts to source (Q11) and sink (Q12) current. Referring to FIG. 7B, further improvement is made by connecting a similar network from the input, Vin, to the base of the output transistors Q23 and Q24 of the Pre-Amplifier Stage 102 by adding the feed-forward network 301c and 301d.

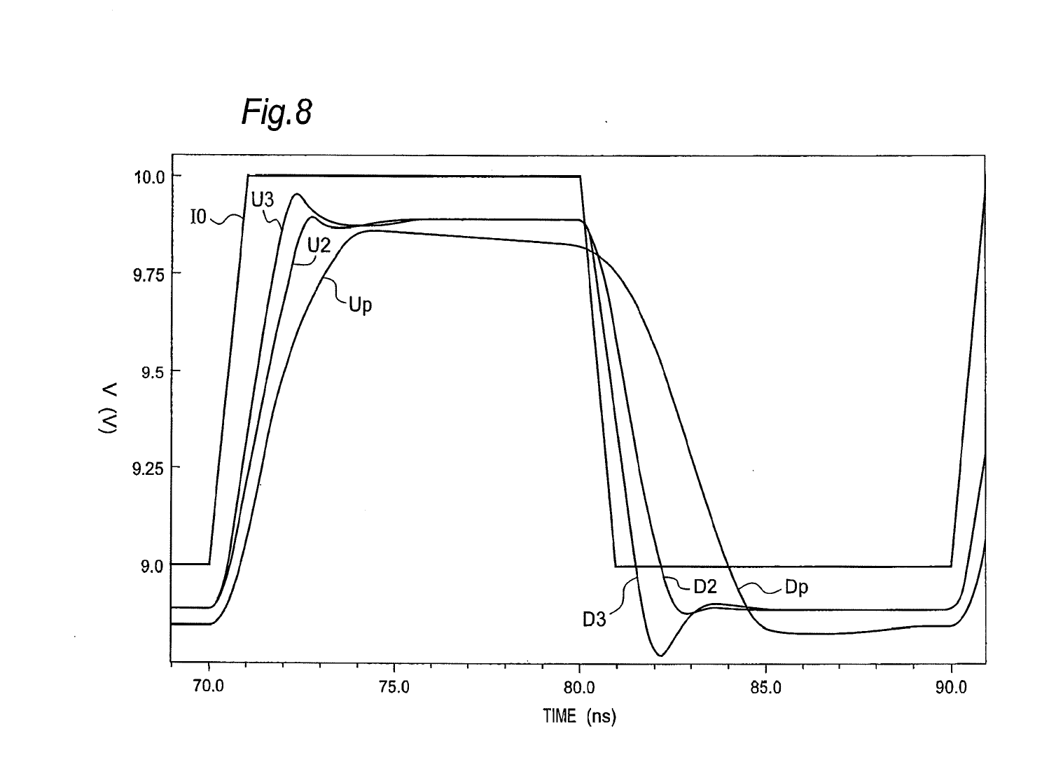

FIG. 8 shows a comparison of the Output Waveform using the conventional art, second preferred embodiment and third preferred embodiment. The simulation is done by adjusting the ICQ to be about 1.4 mA and load of 20 pF in series with a 15 Ohm resistor. A square wave input IO of 1000 V/us (much higher than designed Slew Rate), 1Vₚₑₐₖₜₒₚₑₐₖ, is used in this case to obtain the maximum Slew Rate Achievable by the 3 systems. In the example, the output using the prior art is unable to maintain a constant signal level at signal high and signal low, besides having the worst Slew Rate of the 3 systems.

The results of the simulations are as follows, in which the legends used in FIG. 8 are shown in parenthesis.

### Prior Art

Rise Slew Rate 337V/us (Up)

Fall Slew Rate=249V/us (Dp)

### Second Preferred Embodiment

Rise Slew Rate ˜458V/us (U2)

Fall Slew Rate=471V/us (D2)

### Third Preferred Embodiment

Rise Slew Rate=612V/us (U3)

Fall Slew Rate=755V/us (D3)

In actual CCD buffer application, it is important to maintain a stable signal during sampling of the signal. In the results shown in FIG. 8, the prior art is not able to maintain a stable signal whereas the system used by both the second preferred embodiment and third preferred embodiment is able to maintain the stable signal. The overshoot and undershoot experienced by the invention died down quickly due to the variable current biasing block allowing the signal be held stable faster than the prior art. This is due to the reduction of the charging current of Q13 (in the case of Q14, it will be discharging current) due to variable current biasing block 101a (in the case of Q14, 101b). Furthermore, Q13 is further discharged by transistor Q12 (in the case of Q14, charged by transistor Q11) and the total output current is able to change from high current mode, in terms of mA, to low current mode, in terms of uA, faster and the transition time taken for the change in current mode is much faster.

What is claimed is:

1. A low power, high slew rate output driver comprising:
a high speed pre-amplifier stage to receive an input signal;
a high speed Output Stage to generate the output signal;
a variable current biasing block to sample output biasing current from the said high speed pre-amplifier stage and mirror a multiple of that current to the said high speed output stage.

2. A low power, high slew rate output driver as described in claim 1, wherein said mirrored current is a single multiple of the said sampled current.

3. A low power, high slew rate output driver as described in claim 1, wherein said high speed pre-amplifier stage comprises:
a Class AB Pre-amplifier stage.

4. A low power, high slew rate output driver as described in claim 1, wherein said variable current biasing block comprises a simple current mirror.

5. A low power, high slew rate output driver as described in claim 4, wherein said high speed pre-amplifier stage comprises:
a Class AB Pre-amplifier stage.

6. A low power, high slew rate output driver as described in claim 1, wherein said high speed Output Stage comprises:
a feedforward network.

7. A low power, high slew rate output driver as described in claim 6, wherein said variable current biasing block comprises a simple current mirror.

8. A low power, high slew rate output driver as described in claim 7, wherein said high speed pre-amplifier stage comprises:
a Class AB Pre-amplifier stage.

9. A low power, high slew rate output driver as described in claim 3, wherein said high speed Output Stage drives a load that is equivalent to a capacitor and resistor in series.

10. A low power, high slew rate output driver as described in claim 5, wherein said high speed Output Stage drives a load that is equivalent to a capacitor and resistor in series.

11. A low power, high slew rate output driver as described in claim 8, wherein said high speed Output Stage drives a load that is equivalent to a capacitor and resistor in series.
